(19) United States
(12) Patent Application Publication
(10) Pub. No.: US 2003/0058698 A1
(43) Pub. Date: Mar. 27, 2003

(54) Memory with high performance unit architecture

(76) Inventors: Gerhard Mueller, Meitingen (DE); Toshiaki Kirihata, Poughkeepsie, NY (US)

Correspondence Address: Siemens Corporation, Intellectual Property Department, 186 Wood Avenue South, Iselin, NJ, 08830, US

(21) Appl. No.: 09/964,207

(22) Filed: Sep. 26, 2001

(51) Int. Cl. G11C 7/00

(52) U.S. Cl. 365/200

(57) ABSTRACT

A memory block with improved access time is disclosed. The memory block comprises a plurality of cells interconnected by bitlines in a first direction and wordlines in a second direction. A column decoder is located on a first side of the array along the second direction and a sense amplifier along a second side opposite the first side, resulting in access time reduced by about half compared to conventional memory blocks.

### FIELD OF THE INVENTION

The present invention generally relates to integrated circuits. More particularly, the present invention relates to memory integrated circuits.

### BACKGROUND OF THE INVENTION

FIG. 1 shows a conventional dynamic random access memory unit 100 of an integrated circuit (IC) having a hierarchical column select line architecture. Memory units with hierarchical column select lines are described in, for example, U.S. Pat. No. 5,822,268, which is herein incorporated by reference for all purposes. The memory unit 100 comprises a plurality of memory cell arrays 110. Each array comprises a plurality of memory cells interconnected by wordlines in a first direction and bitlines in a second direction. The bitlines of each array are coupled to sense amplifiers 112. A column decoder 160, second sense amplifier (SSA) 170, and write circuitry 165 are located at the bottom of the unit 100.

To perform a memory access, an address is provided corresponding to the memory cell to be accessed. The address includes a row portion (RADD) and a column portion (CADD). The RADD is decoded by the row decoder. Based on the decoded row address, the appropriate wordline is selected (e.g., activated). The column decoder decodes the CADD and activates the CSL corresponding to the decoded CADD, coupling the bitline (e.g., bitline pair) of the selected cell to the master date line (MDQ). For a write access, the write circuitry drives the information onto the MDQ and writes it into the cell. For a read access, information from the selected memory cell is sensed by the sense amplifier and placed onto the MDQ, which is then reamplified by the SSA.

The read access time partly depends on the propagation delay for the CSL signal from the column decoder to reach the sense amplifier and the information from the sense amplifier of the memory array of the selected memory cell to reach the SSA. Since the distance of the signal path varies depending on the location of the memory cell, variations in read access times result. For example, accessing the memory cell located in memory array 210ₓ at the opposite end 180 of the memory unit produces a propagation delay equal to about 2×L, where L is the length of the memory unit. On the other hand, accessing a memory cell in memory array 210₁ at end 173 produces a much smaller delay. Since the read memory access must take into account the longest or worst case situation, such a large skew in read access adversely impacts performance.

As evident from the foregoing discussion, it is desirable to provide a memory unit architecture, which performs a fast, and more uniform read access time.

### SUMMARY OF THE INVENTION

The invention relates generally to integrated circuits and more particularly to integrated circuits with a memory unit. The memory unit comprises a plurality of cells interconnected by bitlines in a first direction and wordlines in a second direction. In one embodiment, a column decoder is located on a first side of the array along the second direction and a secondary sense amplifier along a second side opposite the first side. A write circuitry is located on the first side of the array. By locating the sense amplifier and column decoder on opposite sides of the array, memory access time dependency with respect to memory dells is eliminated, improving memory access speed and memory cycle times.

### BRIEF DESCRIPTION OF THE DRAWINGS

FIG. 1 shows conventional memory unit architecture;

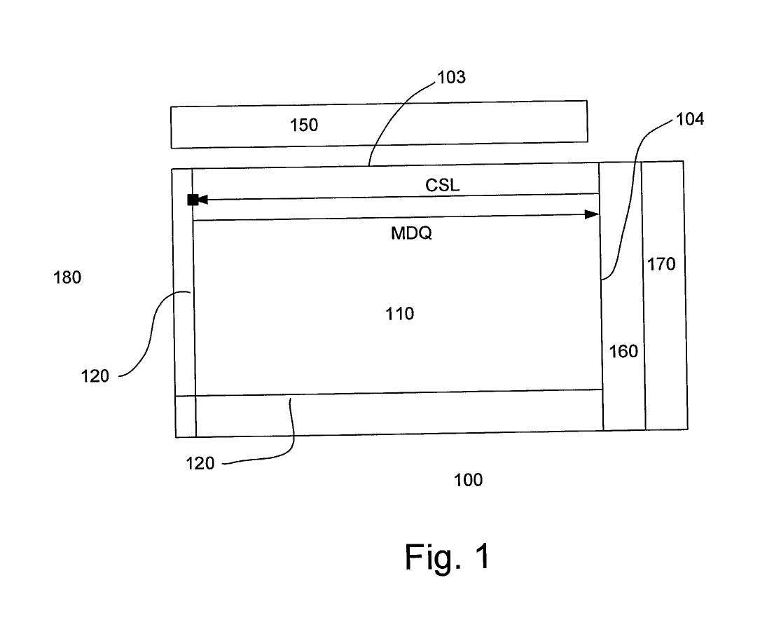

FIG. 2 shows a memory unit architecture in accordance with one embodiment of the invention;

FIG. 3 shows a dynamic random access memory cell; and

FIG. 4 shows a memory IC with memory units in accordance with one embodiment of the invention.

### DESCRIPTION OF THE INVENTION

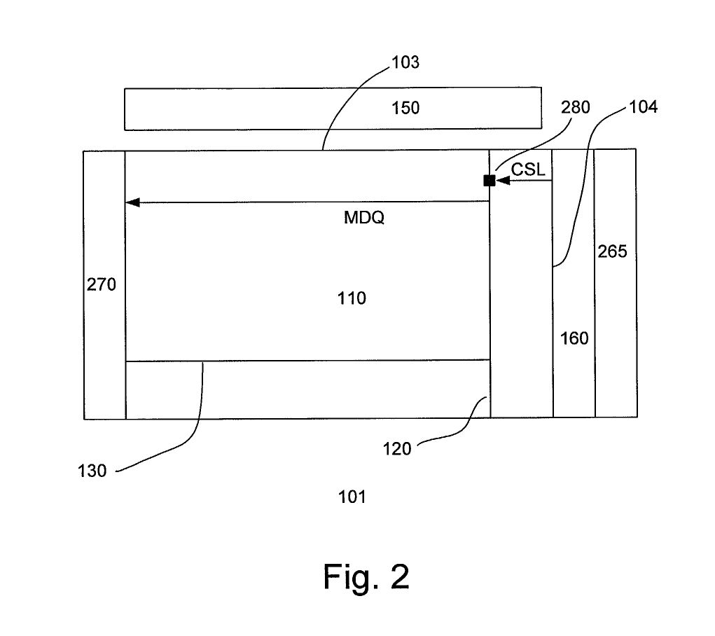

FIG. 2 shows a memory unit 200 in accordance with one embodiment of the invention. The memory unit 200 can be implemented in an IC, such as a memory IC. The memory unit comprises a plurality of memory cell arrays 210₁-210ₓ. Each array comprises a plurality of memory cells 209 interconnected by wordlines (not shown) in a first direction and bitlines (not shown) in a second direction. The bitlines of each array are coupled to sense amplifiers 212₁-212ₓ.

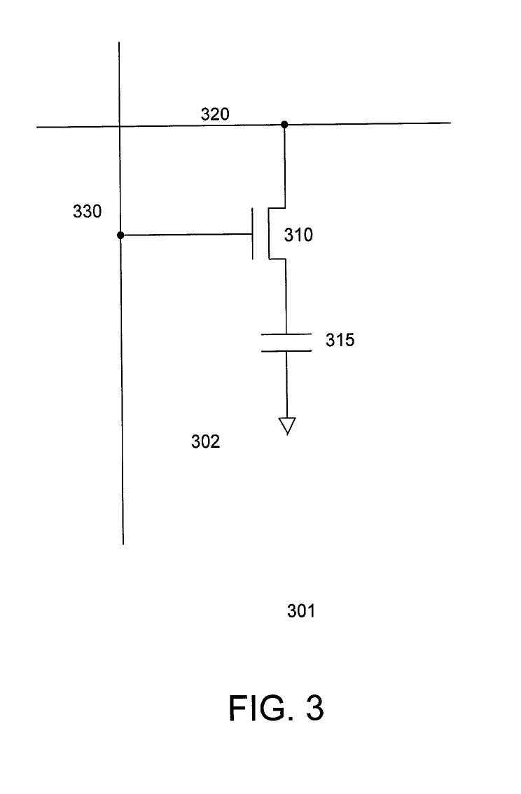

In one embodiment, the memory unit comprises dynamic random access memory (DRAM) cells. Other types of memory cells are also useful. As shown in FIG. 3, a DRAM cell 301 includes a MOS transistor 310 and a capacitor 315. The MOS transistor, for example, is a NMOS transistor having a first terminal coupled to a bitline 320 and a second terminal coupled to a first plate of the capacitor. The use of a PMOS transistor is also useful. A second plate of the capacitor is coupled to a reference voltage 302 such as V_{DD}/2, where V_{DD} is the operating voltage of the IC. The gate of the transistor is coupled to the wordline 330.

The memory unit includes a row decoder 250 along a side of the memory unit in the direction of the bitlines. The row decoder controls the activation of the wordlines. perpendicular to the wordlines. A column decoder 260 is located on a second side of the array perpendicular to the bitlines. The column decoder generates a column select signal on the CSL signal line. In one embodiment, the memory unit comprises an hierarchical CLS architecture. Other types of CSL architectures are also useful. The column select signal selectively couples a bitline from one of the memory arrays to an MDQ line.

In accordance with the invention, an SSA 270 is provided on a side of the memory unit which is opposite to the side where the column decoder is located. A write circuitry 265 is located on the same side as the column decoder (opposite side of the SSA). By providing the SSA and column decoder on the opposite sides of the memory unit, the propagation delay of a read access is substantially equal to about the length L of the memory unit independent of where the memory cell is located. For example, a read access to a memory cell in memory array 210₂ produces a propagation delay for the CSL signal of about a (distance from column decoder to cell) while L—a for the information from the cell to the SSA, resulting in a total delay of about L. Likewise, a read access to memory cell in memory array 210ₓ produces a delay of about b for the CSL signal and L-b delay for the information from the memory cell to the SSA, which results in a total delay substantially equal to L.

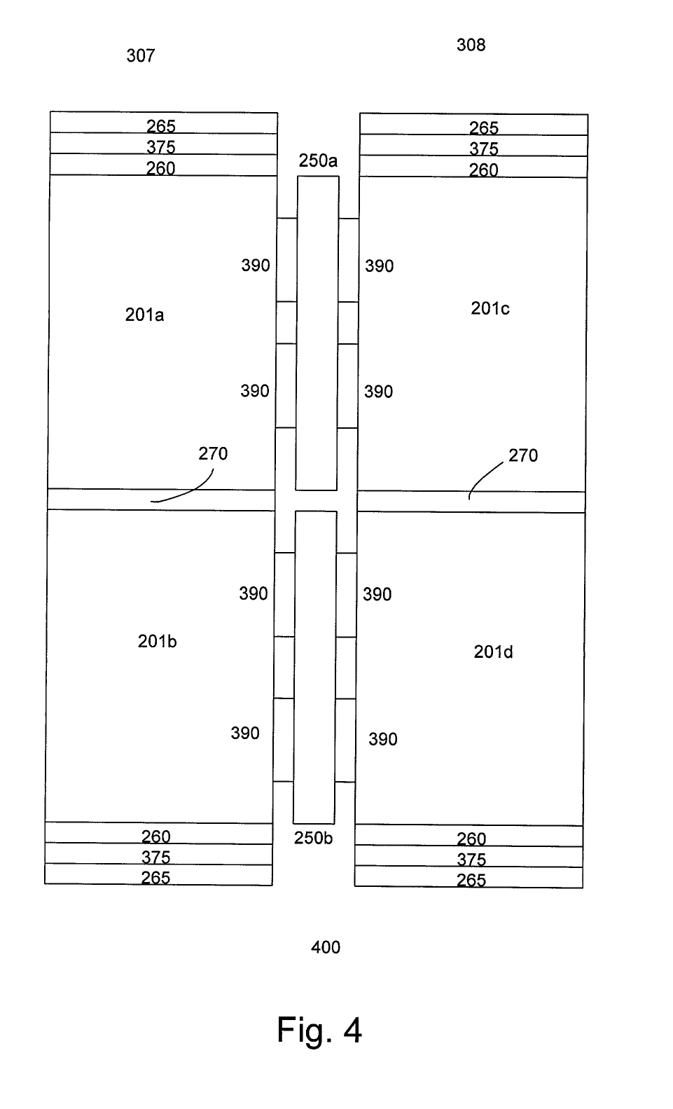

FIG. 4 shows a memory IC 400 with multiple units 201a-d in accordance with one embodiment of the invention. As shown, the memory IC 400 includes four memory units 201a-d arranged in a 2×2 matrix as a four quadrant architecture. Each unit comprises a plurality of memory arrays 202, a column decoder 260, and write circuitry 265. In one embodiment, the memory units 201a and 201c are flipped in the x-direction to allow for the sharing of a row decoder 250a. Likewise, memory units 201b and 201d are flipped to share a row decoder 250b. Two quadrants in the top IC half are flipped by x direction. To share SSA between two memory units, memory units 201a and 201b are flipped in the y-direction as well as memory units 201c and 201. Fuses can be provided. In one embodiment, fuse banks 490 are located between the memory units near the row decoders and fuse banks 475 are located on the sides of the array where the column decoders are located.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claim is:

1. An integrated circuit comprising including a memory unit comprising:
a plurality of memory cells interconnected by bitlines in a first direction and wordlines in a second direction;
a column decoder located along a first side of the memory block in the second direction; and
a sense amplifier located on a second side opposite of the first side of the memory block.

2. The integrated circuit of claim 1 wherein the integrated circuit comprises a memory integrated circuit.

3. The integrated circuit of claim 1 further comprises a row decoder located along a third side of the memory block in the first direction.

4. The integrated circuit of claim 1, 2, or 3 further comprises a write circuitry located along one of the first or second sides of the memory block.

5. The integrated circuit of claim 4 wherein the write circuitry is located along the first side.

6. The integrated circuit of claim 5 further comprises a fuse bank located along one of the first and second side of the memory block.

7. The integrated circuit of claim 5 further comprises a fuse bank located along the side of the memory block with the column decoder.
